(19) United States
(12) Patent Application Publication
(10) Pub. No.: US 2025/0063676 A1
(43) Pub. Date: Feb. 20, 2025

(54) ELECTRONIC DEVICE INCLUDING SUBSTRATE INCLUDING COATING LAYER

(71) Applicant: Samsung Electronics Co., Ltd., Suwon-si (KR)

(72) Inventors: Youngsun LEE, Suwon-si (KR); Byeongkeol KIM, Suwon-si (KR); Sungjin KIM, Suwon-si (KR); Jaeyeon RA, Suwon-si (KR); Yongjae SONG, Suwon-si (KR); Jongmin JEON, Suwon-si (KR)

(21) Appl. No.: 18/937,936

(22) Filed: Nov. 5, 2024

Related U.S. Application Data
(63) Continuation of application No. PCT/KR2023/005996, filed on May 2, 2023.

(30) Foreign Application Priority Data
May 17, 2022 (KR) 10-2022-0060506
Sep. 22, 2022 (KR) 10-2022-0120349

(51) Int. Cl. H05K 5/02; H05K 1/02; H05K 1/14; H05K 7/14

(52) U.S. Cl. CPC H05K 5/0226; H05K 1/028; H05K 1/14; H05K 7/1427

(57) ABSTRACT

An electronic device comprises: a first housing; a second housing; a hinge structure comprising a hinge rotatably connecting the first housing with the second housing; and a substrate including a flexible portion, a rigid portion, and a stepped portion arranged at a boundary between the flexible portion and the rigid portion. The substrate comprises: a first conductive layer arranged in the flexible portion and the rigid portion; a first coating layer arranged on a portion of the first conductive layer corresponding to the rigid portion; a second conductive layer arranged on the first coating layer in the rigid portion; and a second coating layer arranged on the second conductive layer. A portion of the boundary of the first coating layer is aligned in the stepped portion.

### CROSS-REFERENCE TO RELATED APPLICATIONS

This application is a continuation of International Application No. PCT/KR2023/005996 designating the United States, filed on May 2, 2023, in the Korean Intellectual Property Receiving Office and claiming priority to Korean Patent Application Nos. 10-2022-0060506, filed on May 17, 2022, and 10-2022-0120349, filed on Sep. 22, 2022, in the Korean Intellectual Property Office, the disclosures of each of which are incorporated by reference herein in their entireties.

### BACKGROUND

### Field

The disclosure relates to an electronic device including a substrate including a coating layer.

### Description of Related Art

An electronic device including a large-screen display may increase utilization of a user. As a demand for the electronic device with high portability increases, the electronic device may include a deformable display. The deformable display may be slidably deformable, or foldable deformable, or rollable deformable.

The above-described information may be provided as a related art for the purpose of helping to understand the present disclosure. No claim or determination is raised as to whether any of the above-described information may be applied as a prior art related to the present disclosure.

### SUMMARY

An electronic device according to an example embodiment may include: a first housing, a second housing, a hinge structure comprising a hinge, and a substrate. The hinge structure may rotatably connect the first housing and the second housing. The substrate may extend from an inside of the first housing across the hinge structure to an inside of the second housing. The substrate may include a flexible portion, a rigid portion, and a stepped portion. The stepped portion may be disposed at the boundary between the flexible portion and the rigid portion. The substrate may include a first conductive layer, a first coating layer, a second conductive layer, and a second coating layer. The first conductive layer may be disposed in the flexible portion and the rigid portion. The first coating layer may be disposed on a portion of the first conductive layer corresponding to the rigid portion. The second conductive layer may be disposed on the first coating layer in the rigid portion. The second coating layer may be disposed on the second conductive layer. A portion of a boundary of the first coating layer may be aligned with the stepped portion.

A method of manufacturing a substrate according to an example embodiment may include: disposing a first conductive layer on a dielectric film, disposing a non-conductive layer on the first conductive layer, coating a first coating layer on the non-conductive layer, disposing a rigid portion including a second conductive layer on a portion of the first coating layer, forming a via hole in the rigid portion and removing a smear of the formed via hole, coating a second coating layer on the second conductive layer, and removing the first coating layer disposed in a flexible portion of the first coating layer.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2A is a diagram illustrating an unfolded state of an example electronic device according to various embodiments;

FIG. 2B is a diagram illustrating a folded state of an example electronic device according to various embodiments;

FIG. 2C is an exploded perspective view of an example electronic device according to various embodiments;

FIG. 3A is a diagram illustrating a portion of an example electronic device in an unfolded state according to various embodiments;

FIG. 3B is a cross-sectional view of an example electronic device taken along line A-A′ of FIG. 3A according to various embodiments;

FIG. 4A is a diagram illustrating a plan view of an example substrate according to various embodiments;

FIG. 4B is a cross-sectional view of an example substrate taken along line B-B′ of FIG. 4A according to various embodiments;

FIG. 5 is a flowchart illustrating an example method of manufacturing an example substrate according to various embodiments;

FIGS. 6, 7, 8, 9, and 10 are cross-sectional views illustrating an example substrate during a manufacturing process according to various embodiments.

### DETAILED DESCRIPTION

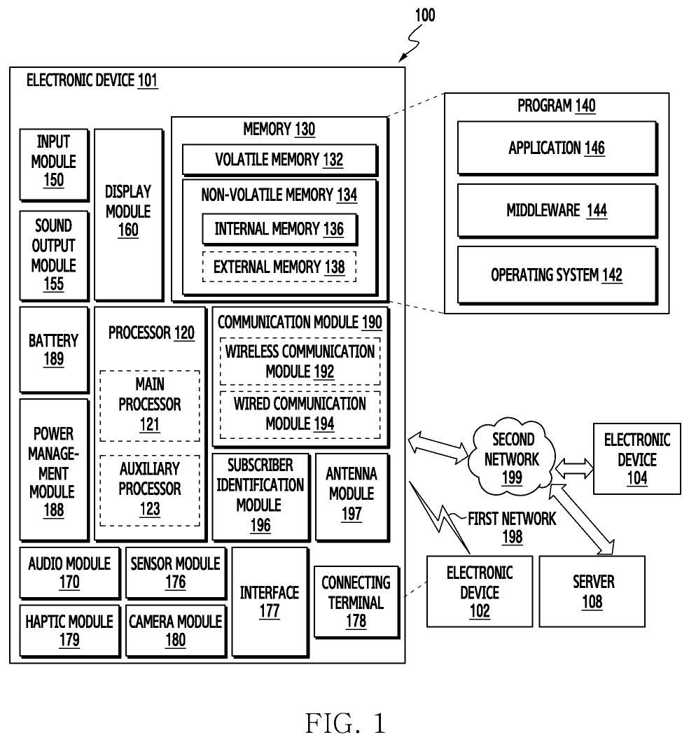

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (cMBB), massive machine type communications (mMTC), or ultra-reliable and low-latency communications (URLLC). The wireless communication module 192 may support a high-frequency band (e.g., the mm Wave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing cMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

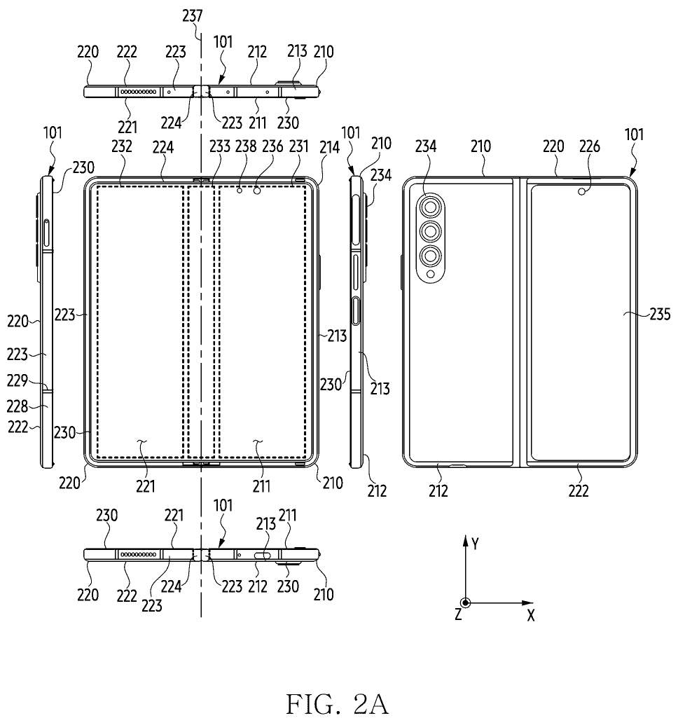

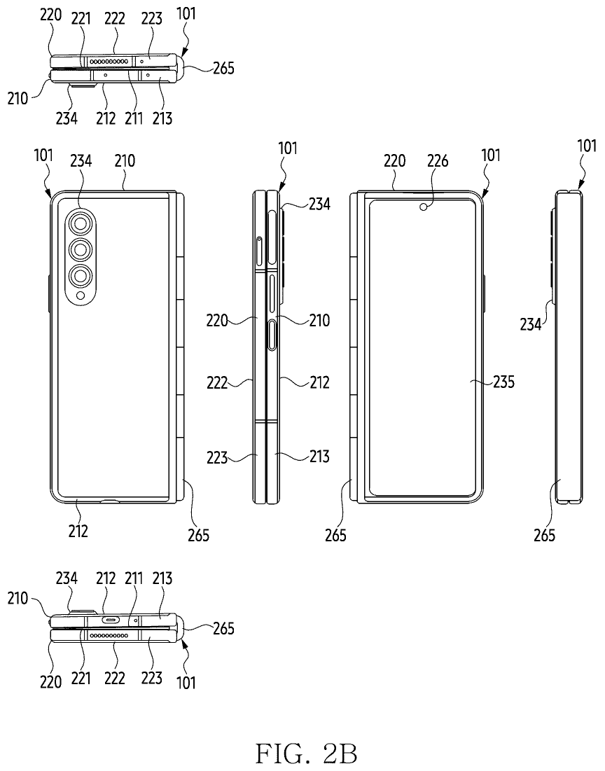

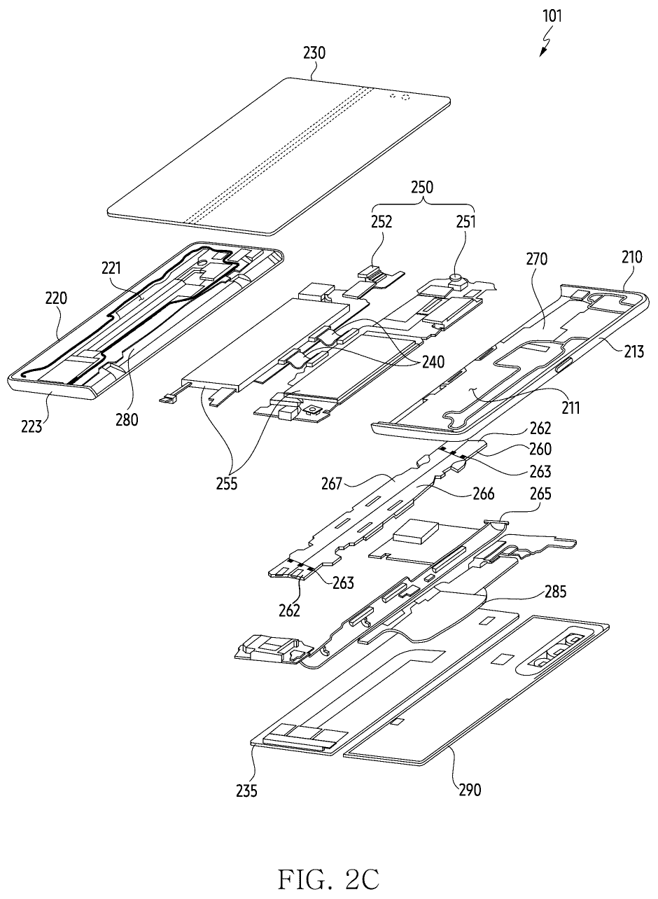

FIG. 2A is a diagram illustrating an unfolded state of an example electronic device 101 according to various embodiments. FIG. 2B is a diagram illustrating a folded state of the example electronic 101 device according to various embodiments. FIG. 2C is an exploded perspective view of the example electronic device 101 according to various embodiments.

Referring to FIGS. 2A, 2B, and 2C, the electronic device 101 may include a first housing 210, a second housing 220, and a display 230. The electronic device 101 may be a device in which the first housing 210 and the second housing 220 may contact each other. The electronic device 101 may be referred to as a foldable electronic device.

In an embodiment, the first housing 210 may include a first surface 211, a second surface 212 opposite to the first surface 211, and a first side surface 213 covering at least a portion of the first surface 211 and the second surface 212. In an embodiment, the second surface 212 may further include at least one camera 234 exposed through a portion of the second surface 212. In an embodiment, the first housing 210 may include a first protection member 214 disposed along a periphery of the first surface 211. In an embodiment, the first housing 210 may provide a space formed by the first surface 211, the second surface 212, and the first side surface 213 as a space for mounting components of the electronic device 101. In an embodiment, the first side surface 213 and a second side surface 223 may include a conductive material, a non-conductive material, or a combination thereof. For example, the second side surface 223 may include a conductive portion 228 and a non-conductive portion 229. The conductive portion 228 may include a plurality of conductive portions spaced apart from each other. The non-conductive portion 229 may be disposed between the plurality of conductive portions. An antenna structure may be formed by a portion of the plurality of conductive portions and the plurality of non-conductive portions, or a combination thereof.

In an embodiment, the second housing 220 may include a third surface 221, a fourth surface 222 opposite to the third surface 221, and the second side surface 223 covering at least a portion of the third surface 221 and the fourth surface 222. In an embodiment, the fourth surface 222 may further include a sub-display 235 disposed on the fourth surface 222. A camera 226 may be disposed to face the fourth surface 222 inside the second housing 220 to obtain an external image through the fourth surface 222. The camera 226 may be disposed below the sub-display 235 and visually covered by the sub-display 235. The display 230 distinguished from the sub-display 235 may be referred to as a main-display. In an embodiment, the camera 226 is disposed under the sub-display 235, and the sub-display 235 may include an opening aligned with the camera 226 lens to transmit light from an outside to the camera 226. According to an embodiment, each of the first housing 210 and the second housing 220 may include each of the first protection member 214 and a second protection member 224. The first protection member 214 and the second protection member 224 may be disposed on the first surface 211 and the third surface 221 along a periphery of the display 230. The first protection member 214 and the second protection member 224 may prevent or block a foreign substance (e.g., dust or moisture) from being introduced through a gap between the display 230 and the first housing 210 and the second housing 220. The first protection member 214 may be disposed along a periphery of a first display region 231, and the second protection member 224 may be disposed along a periphery of a second display region 232. The first protection member 214 may be formed by being attached to the first side surface 213 of the first housing 210, or may be integrally formed with the first side surface 213. The second protection member 224 may be formed by being attached to the second side surface 223 of the second housing 220, or may be integrally formed with the second side surface 223.

In an embodiment, the second side surface 223 may be rotatably (or pivotably) connected to the first side surface 213 through a hinge structure 260 mounted on a hinge cover 265. The hinge structure 260 may include a hinge module 262, a first hinge plate 266, and a second hinge plate 267. The first hinge plate 266 may be connected to the first housing 210, and the second hinge plate 267 may be connected to the second housing 220. In an embodiment, the second housing 220 may provide a space formed by the third surface 221, the fourth surface 222, which faces the third surface 221 and is spaced apart, and the side surface 223 covering at least a portion of the third surface 221 and the fourth surface 222 as a space for mounting the components of the electronic device 101. According to an embodiment, the display 230 may include a window exposed toward the outside. The window may protect the surface of the display 230 and be formed as a protective layer to transmit visual information provided by the display 230 to the outside. The window may include a glass material such as an ultra-thin glass (UTG) or a polymer material such as a polyimide (PI). According to an embodiment, the display 230 may be disposed on the first surface 211 of the first housing 210 and the third surface 221 of the second housing 220 across the hinge cover 265. The display 230 may include the first display region 231 disposed on the first surface 211 of the first housing 210, the second display region 232 disposed on the third surface 221 of the second housing 220, and a third display region 233 disposed between the first display region 231 and the second display region 232. The first display region 231, the second display region 232, and the third display region 233 may form a front surface of the display 230.

According to an embodiment, an opening may be formed in a portion of a screen display region of the display 230, or a recess or opening may be formed in a support member (e.g., bracket) supporting the display 230. The electronic device 101 may include at least one of a sensor module 238 aligned with the recess or the opening, and a camera 236. For example, the first display region 231 may further include the camera 236 capable of obtaining an image from the outside through the portion of the first display region 231 and the sensor module 238 generating an electrical signal or a data value corresponding to an external environmental condition. According to an embodiment, at least one of the sensor module 238 and the camera 236 may be included on a rear surface of the display 230 corresponding to the first display region 231 or the second display region 232 of the display 230. For example, at least one of the camera 236 and the sensor module 238 may be disposed under the display 230 and covered by the display 230. At least one of the camera 236 and the sensor module 238 may not be exposed to the outside by being covered by the display 230. However, the disclosure is not limited thereto, and the display 230 may include the opening exposing the camera 236 and the sensor module 238 to the outside. Although not illustrated in FIGS. 2A and 2B, in an embodiment, the display 230 may further include the rear surface opposite to the front surface. In an embodiment, the display 230 may be supported by a first support member 270 of the first housing 210 and a second support member 280 of the second housing 220.

In an embodiment, the hinge structure 260 may be configured to form the first housing 210, form the first support member 270 fastened to the first hinge plate 266 and the second housing 220, and rotatably connect the second support member 280 fastened to the second hinge plate 267.

In an embodiment, the hinge cover 265 covering the hinge structure 260 may be at least partially exposed through a space between the first housing 210 and the second housing 220 while the electronic device 101 is in a folded state. In an embodiment, the hinge cover 265 may be covered by the first housing 210 and the second housing 220 while the electronic device 101 is in an unfolded state.

In an embodiment, the electronic device 101 may be folded with respect to a folding axis 237 passing through the hinge cover 265. For example, the hinge cover 265 may be disposed between the first housing 210 and the second housing 220 of the electronic device 101 so that the electronic device 101 may be bent, curved, or folded. For example, the first housing 210 may be connected to the second housing 220 through the hinge structure 260 mounted on the hinge cover 265 and may rotate with respect to the folding axis 237. For example, the hinge structure 260 may include the hinge modules 262 disposed at both ends of the first hinge plate 266 and the second hinge plate 267. Since the hinge module 262 includes hinge gears engaged with each other therein, the hinge module 262 may rotate the first hinge plate 266 and the second hinge plate 267 with respect to the folding axis 237. The first housing 210 coupled to the first hinge plate 266 may be connected to the second housing 220 coupled to the second hinge plate 267, and may rotate with respect to the folding axis by hinge modules 262.

In an embodiment, the electronic device 101 may be folded so that the first housing 210 and the second housing 220 may face each other by rotating with respect to the folding axis 237. In an embodiment, the electronic device 101 may be folded so that the first housing 210 and the second housing 220 are folded or overlap each other.

Referring to FIG. 2C, the electronic device 101 may include the first support member 270, the second support member 280, the hinge structure 260, the display 230, a printed circuit board 250, a battery 255, the hinge cover 265, an antenna 285, the sub-display 235, and a rear plate 290. According to an embodiment, the electronic device 101 may omit at least one of the components or may additionally include another component. At least one of the components of an electronic device 300 may be the same as or similar to at least one of the components of the electronic device 101 of FIG. 1, 2A, or 2B, and a redundant description will be omitted below.

The first housing 210 and the second housing 220 may support a flexible display (e.g., the display 230 of FIG. 2A). A flexible display panel may include a front surface that provides information by emitting light and a rear surface facing the front surface. In case that the first surface (e.g., the first surface 211 of FIG. 2A) of the first housing 210 faces the third surface (e.g., the third surface 221 of FIG. 2A) of the second housing 220, the flexible display panel may be in the folded state in which a surface in which the first display region 231 of the flexible display panel faces and a surface in which the second display region 232 faces face each other. In case that the first surface 211 of the first housing 210 and the third surface 221 of the second housing 220 face substantially the same direction, the display 230 may be in the unfolded state in which the first display region 231 and the second display region 232 of the display 230 face the same direction. The display 230 may be referred to as the flexible display in terms of being deformed according to a state of the electronic device.

In an embodiment, the electronic device 101 may provide the unfolded state in which the first housing 210 and the second housing 220 are fully unfolded by the hinge structure 260. The first support member 270 may switch the electronic device 101 into the folded state or the unfolded state by being connected to the second support member 280 through the hinge structure 260. By rotation of the hinge gear 263, the first support member 270 and the second support member 280 attached to the hinge plates 266 and 267 of the hinge structure 260 may operate. The hinge plates 266 and 267 may include the first hinge plate 266 coupled to the first support member 270 and the second hinge plate 267 coupled to the second support member 280. By the rotation of the hinge gear 263, the electronic device 101 may be switched to the folded state or the unfolded state.

The hinge structure 260 may include the hinge module 262, the first hinge plate 266, and the second hinge plate 267. The hinge module 262 may include the hinge gear 263 capable of pivoting the first hinge plate 266 and the second hinge plate 267. The hinge gear 263 may rotate the first hinge plate 266 and the second hinge plate 267 while engaging with each other and rotating. The hinge module 262 may be a plurality of hinge modules. Each of the plurality of hinge modules may be disposed at both ends formed by the first hinge plate 266 and the second hinge plate 267.

The first hinge plate 266 may be coupled to the first support member 270 of the first housing 210, and the second hinge plate 267 may be coupled to the second support member 280 of the second housing 220. The first housing 210 and the second housing 220 may rotate to correspond to the rotation of the first hinge plate 266 and the second hinge plate 267.

The first housing 210 may include the first support member 270. The second housing 220 may include the second support member 280. The first support member 270 may be partially covered by the first side surface 213, and the second support member 280 may be partially covered by the second side surface 223. The first support member 270 may be integrally formed with the first side surface 213, and the second support member 280 may be integrally formed with the second side surface 223. According to an embodiment, the first support member 270 may be formed separately from the first side surface 213, and the second support member 280 may be formed separately from the second side surface 223. The first side surface 213 and the second side surface 223 may be formed by a metal material, a non-metal material, or a combination thereof, and may be used as an antenna.

A surface of the first support member 270 may be coupled to the display 230, and another surface of the first support member 270 may be coupled to the rear plate 290. A surface of the second support member 280 may be coupled to display 230 and another surface of the second support member 280 may be coupled to the sub-display 235.

The electronic device 101 may include the printed circuit board 250 and the battery 255. The printed circuit board 250 may include a first printed circuit board 251 disposed on the first support member 270 and a second printed circuit board 252 disposed on the second support member 280. A shape of the first printed circuit board 251 and a shape of the second printed circuit board 252 may be different from each other according to a space of the inside of the electronic device. Components for implementing various functions of the electronic device 101 may be mounted on the first printed circuit board 251 and the second printed circuit board 252. According to an embodiment, components for implementing main functions of the electronic device 101 may be mounted on the first printed circuit board 251, and electronic components for implementing a portion of functions of the first printed circuit board 251 or components for driving the sub-display 235 disposed on the fourth surface 222 may be disposed on the second printed circuit board 252. The first printed circuit board 251 and the second printed circuit board 252 may be electrically connected to each other by a flexible printed circuit board 240.

For example, the battery 255, which is a device for supplying power to at least one component of the electronic device 101, may include a non-rechargeable primary battery, or a rechargeable secondary battery, or a fuel cell. At least portion of the battery 255 may be disposed on substantially on a same plane as the printed circuit board 250. The same plane, where the printed circuit board 250 and the battery 255 are disposed, may be disposed on a surface (e.g., a surface facing the second surface 212 and fourth surface 222, or a surface facing the sub-display 235 and the rear plate 290). For example, the display 230 may be disposed on the first surface 211 and the third surface 221, and the printed circuit board 250 and the battery 255 may be disposed on the second surface 212 and the fourth surface 222, facing the surface on which the display 230 is disposed.

In an embodiment, the antenna 285 may be disposed between the rear plate 290 and the battery 255. For example, the antenna 285 may include a near field communication (NFC) antenna, a wireless charging antenna, and/or a magnetic secure transmission (MST) antenna. For example, the antenna 285 may perform short-range communication with an external device, or wirelessly transmit and receive power required for charging.

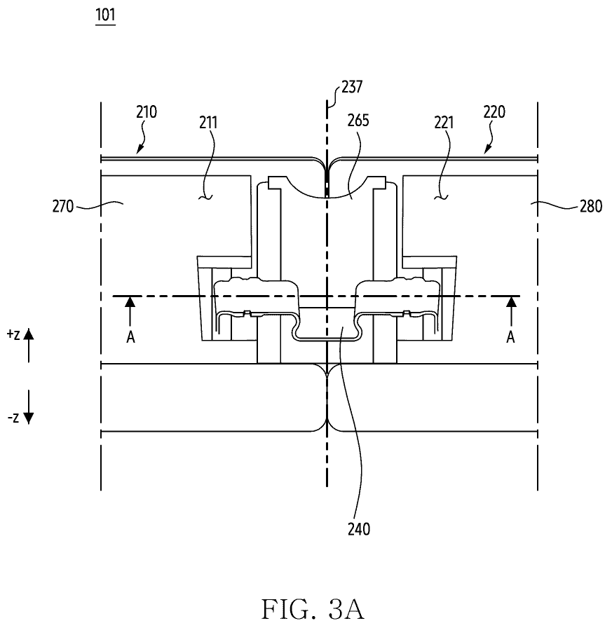

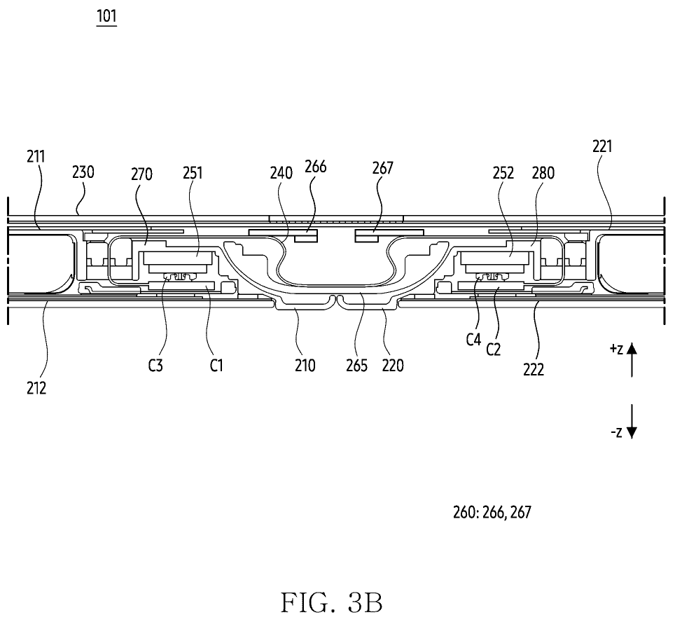

FIG. 3A is a diagram illustrating a portion of an example electronic device in an unfolded state according to various embodiments. FIG. 3B is a cross-sectional view of an example electronic device taken along A-A′ line of FIG. 3A according to various embodiments.

Referring to FIGS. 3A and 3B, an electronic device 101 according to an embodiment may include a first housing 210, a second housing 220, a hinge structure 260, and a substrate 240 (e.g., the flexible printed circuit board 240 of FIG. 2C).

The electronic device 101 according to an embodiment may be a device including the first housing 210 and the second housing 220 that may be unfolded or folded each other. The electronic device 101 according to an embodiment may be referred to as a foldable electronic device.

According to an embodiment, the first housing 210 may include a first surface 211 facing a first direction (e.g., +z direction) and a second surface 212 facing a second direction (e.g., −z direction) opposite to the first direction. According to an embodiment, the second housing 220 may include a third surface 221 facing the first direction and a fourth surface 222 facing the second direction.

According to an embodiment, the hinge structure 260 may rotatably connect the first housing 210 and the second housing 220 each other. For example, the second housing 220 may be rotated with respect to the first housing 210 through the hinge structure 260. By rotation of the second housing 220 with respect to the first housing 210, the electronic device 101 may be switched to a folded state or an unfolded state. The hinge structure 260 may be configured to provide the folded state, the unfolded state, or intermediate states between the folded state and the unfolded state of the electronic device 101. According to an embodiment, the hinge structure 260 may fix a position of the first housing 210 and the second housing 220 in an intermediate state in which an angle between the first housing 210 and the second housing 220 has a predetermined angle (e.g., about 90 degrees). The predetermined angle may be greater than an angle between the first housing 210 and the second housing 220 in the folded state and less than an angle between the first housing 210 and the second housing 220 in the unfolded state. For example, the hinge structure 260 may include a first hinge plate 266 connected to the first housing 210 and a second hinge plate 267 connected to the second housing 220.

According to an embodiment, when the electronic device 101 is in the unfolded state, the first housing 210 and the second housing 220 may form substantially the same plane. For example, in the unfolded state, the direction of the first surface 211 and the direction of the third surface 221 may be substantially the same. When the electronic device 101 is in the unfolded state, the first surface 211 and the third surface 221 may face the same direction (e.g., +z direction).

According to an embodiment, when the electronic device 101 is in the folded state, the first housing 210 and the second housing 220 may face each other. For example, in the folded state, the first surface 211 and the third surface 221 may face each other. When the electronic device 101 is in the folded state, the direction of the first surface 211 may be opposite to the direction of the third surface 221.

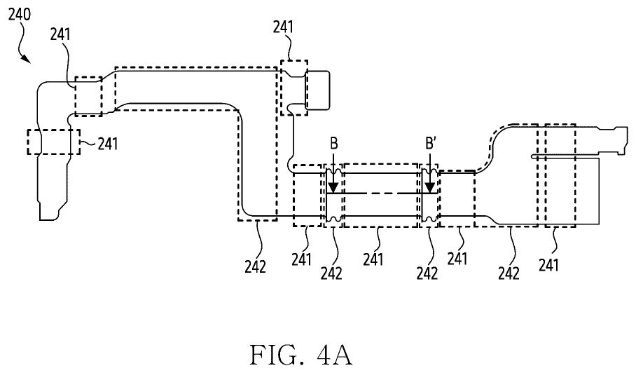

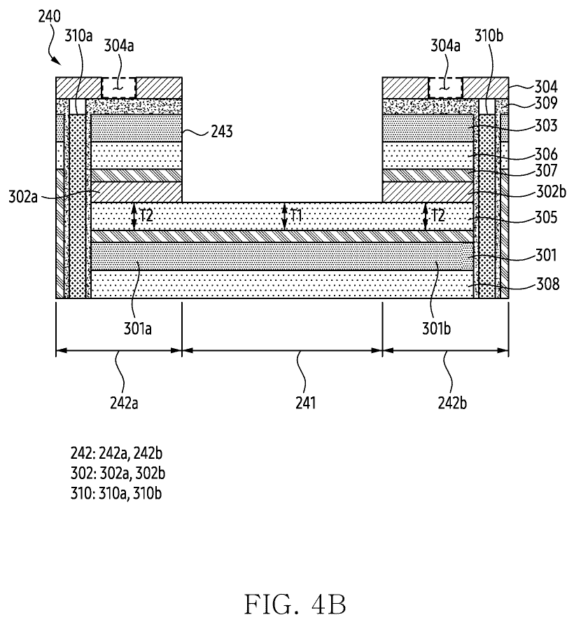

The electronic device 101 according to an embodiment may include a first printed circuit board (PCB) 251 and a second printed circuit board 252. The first printed circuit board 251 may be disposed in the first housing 210. The second printed circuit board 252 may be disposed in the second housing 220. The first printed circuit board 251 and the second printed circuit board 252 may include a plurality of conductive layers and a plurality of non-conductive layers alternately laminated with the plurality of the conductive layers. The first printed circuit board 251 and the second printed circuit board 252 may provide an electrical connection between various electronic components of the electronic device 101, using wirings formed in the conductive layer and conductive vias (e.g., a conductive via 310 of FIG. 4B).

According to an embodiment, the substrate 240 may electrically connect the first printed circuit board 251 and the second printed circuit board 252. For example, the substrate 240 may be configured to transmit an electrical signal from the first printed circuit board 251 to the second printed circuit board 252. For example, the substrate 240 may electrically connect components disposed in the first housing 210 and components disposed in the second housing 220.

According to an embodiment, the substrate 240 may cross between the first printed circuit board 251 and the second printed circuit board 252 to electrically connect the first printed circuit board 251 and the second printed circuit board 252. For example, the substrate 240 may extend from the first printed circuit board 251 in the first housing 210 across the hinge structure 260 to the second printed circuit board 252 in the second housing 220.

According to an embodiment, the substrate 240 may include a region (e.g., a flexible portion) having a shape that is at least partially deformed, based on a rotational operation of the first housing 210 and the second housing 220. According to an embodiment, the substrate 240 may be referred to as the flexible printed circuit board 240 of FIG. 3C. Since the substrate 240 extends from an inside of the first housing 210 across the hinge structure 260 to an inside of the second housing 220, the shape of the substrate 240 may be at least partially deformed, based on a folding operation in which the electronic device 101 changes from the unfolded state to the folded state and/or an unfolding operation in which the electronic device 101 changes from the folded state to the unfolded state.

According to an embodiment, the substrate 240 may include a first connector C1 attached to an end extending into the inside of the first housing 210 and a second connector C2 attached to an end extending into the inside of the second housing 220. The first printed circuit board 251 may include a third connector C3 connected to the first connector C1. The second printed circuit board 252 may include a fourth connector C4 connected to the second connector C2. By connecting the first connector C1 and the third connector C3 and connecting the second connector C2 and the fourth connector C4, one end of the flexible printed circuit board 240 may be fixed to the first printed circuit board 251, and another end of the flexible printed circuit board 240 may be fixed to the second printed circuit board 252.

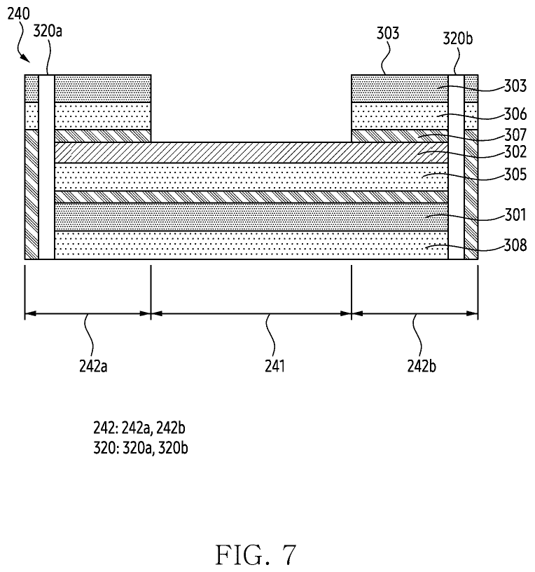

The substrate 240 may include the plurality of conductive layers. For example, the plurality of the conductive layers may be stacked on each other with a non-conductive layer interposed therebetween. The plurality of the conductive layers of the flexible printed circuit board 240 may be electrically connected to each other through a conductive via (e.g., the conductive via 310 of FIG. 4B). A via hole (e.g., a via hole 320 of FIG. 7) penetrating at least a portion of the plurality of the conductive layers may be formed, using a mechanical drill and/or a laser drill. The conductive via 310 may be formed by plating an inner peripheral surface of the via hole 320. In order to remove a smear (e.g., burr, chip, and/or resin residue) generated in a process of drilling the via hole 320, and to clean a surface of the substrate 240, a desmear process using chemicals may be performed.

According to an embodiment, the electronic device 101 may repeat the folding operation and the unfolding operation. For example, the electronic device 101 may be maintained in the unfolded state of the electronic device 101. The electronic device 101 may be maintained in the folded state or the intermediate status of the electronic device 101. As the state of the electronic device 101 changes repeatedly, the shape of at least a portion of the substrate 240 may be repeatedly deformed. As the first housing 210 and the second housing 220 move to be folded with each other with respect to a folding axis 237, or the first housing 210 and the second housing 220 move to be unfolded with each other, at least the portion of the substrate 240 may be repeatedly curved and unfolded. As at least the portion of the substrate 240 is repeatedly curved and unfolded, a deformed portion may be damaged. For example, as an outermost layer (e.g., polyimide coverlay film) of the deformed portion reacts with the chemicals used in the desmear process, durability of the flexible portion (e.g., the flexible portion 241 of FIG. 4A) may be weakened. The flexible portion 241 with weakened durability may be easily damaged by repeatedly being curved and being unfolded. In order to enhance the durability of the deformed portion, a coating layer protecting the outermost layer of the deformed portion may be used during the desmear process. During a post-treatment process, the coating layer may be removed.

FIG. 4A is a diagram illustrating a plan view of an example substrate according to various embodiments. FIG. 4B is a cross-sectional view of an example substrate taken along line B-B′ of FIG. 4A according to various embodiments.

Referring to FIGS. 4A and 4B, the substrate 240 may include a flexible portion 241, a rigid portion 242, and a stepped portion (e.g., the stepped portion 243 of FIG. 4B). A shape of the flexible portion 241 may be deformed by being curved and being unfolded. In order to provide flexibility, a thickness of the flexible portion 241 may be thinner than a thickness of the rigid portion 242. Due to a difference between the thickness of the flexible portion 241 and the thickness of the rigid portion 242, the stepped portion 243 may be formed at the boundary between the flexible portion 241 and the rigid portion 242. A thickness of the stepped portion 243 may correspond to the difference between the thickness of the rigid portion 242 and the thickness of the flexible portion 241.

Referring to FIG. 4A, the substrate 240 may include the flexible portion 241 and the rigid portion 242. The substrate 240 may be referred to as a flexible printed circuit board (FPCB) 240 or a rigid-flexible printed circuit board (RFPCB) 240, but is not limited thereto. The rigid portion 242 may be rigid compared to the flexible portion 241. For example, the flexibility of the flexible portion 241 may be higher than the flexibility of the rigid portion 242. According to an embodiment, the rigid portion 242 may be fixed by being connected to the first printed circuit board 251 or the second printed circuit board 252. As the rigid portion 242 is fixed to the first printed circuit board 251 or the second printed circuit board 252, the substrate 240 may be stably coupled to the first printed circuit board 251 or the second printed circuit board 252. The flexible portion 241 may be at least partially curved, based on a folding operation or an unfolding operation of the first housing 210 and the second housing 220. The flexible portion 241 may be formed in a region where the substrate 240 is curved. For example, the flexible portion 241 may be formed in at least a portion of a region disposed in the hinge cover 265, at least a portion of a region between a connector (e.g., the first connector C1 of FIG. 3B) connected to the first printed circuit board 251 and the rigid portion 242, and/or at least a portion of a region between a connector (e.g., the second connector C2 of FIG. 3B) connected to the second printed circuit board 252 and the rigid portion 242, among an entire region of the substrate 240. However, the disclosure is not limited to thereto.

According to an embodiment, the substrate 240 may include a first conductive layer 301, a second conductive layer 303, a first coating layer 302, and/or a second coating layer 304. The first conductive layer 301 and the second conductive layer 303 may be copper foil, but are not limited thereto. The first conductive layer 301 and/or the second conductive layer 303 may be configured to provide a transmission path of an electrical signal. For example, the first conductive layer 301 and/or the second conductive layer 303 may be configured to transmit the electrical signal between the first printed circuit board 251 and the second printed circuit board 252.

According to an embodiment, the first conductive layer 301 may be disposed in the flexible portion 241 and the rigid portion 242. The first conductive layer 301 may extend from the flexible portion 241 to the rigid portion 242. For example, the first conductive layer 301 may be disposed on a dielectric film 308 disposed in the flexible portion 241 and the rigid portion 242. The first conductive layer 301 may include a portion of the first conductive layer 301 corresponding to the rigid portion 242 and another portion of the first conductive layer 301 corresponding to the flexible portion 241.

According to an embodiment, the first coating layer 302 may be disposed on a portion of the first conductive layer 301 corresponding to the rigid portion 242. The first coating layer 302 may not be disposed on the first conductive layer 301 corresponding to the flexible portion 241. As described later, the first coating layer 302 may be disposed on the first conductive layer 301 in a manufacturing process of the substrate 240 according to an embodiment. In the manufacturing process of the substrate 240, a portion of the entire region of the first coating layer 302, which is disposed on the portion of the first conductive layer 301 corresponding to the rigid portion 242, may not be removed by at least partially overlapping other layers (e.g., the second conductive layer 303 and a second non-conductive layer 306). A portion of the entire region of the first coating layer 302, which is disposed on another portion of the first conductive layer 301 corresponding to the flexible portion 241, may be removed in the manufacturing process of the substrate 240.

According to an embodiment, the substrate 240 may include a non-conductive layer 305 disposed between the first coating layer 302 and the first conductive layer 301. The first non-conductive layer 305 may protect and insulate the first conductive layer 301. For example, the first non-conductive layer 305 may be a coverlay film including polyimide (PI), but is not limited thereto. Among the entire region of the first non-conductive layer 305, a portion of the first non-conductive layer 305 corresponding to the flexible portion 241 may be exposed. Among the entire region of the first non-conductive layer 305, the remaining portion of the first non-conductive layer 305 corresponding to the rigid portion 242 may be at least partially overlapped with other layers (e.g., the second conductive layer 303 and the second non-conductive layer 306).

According to an embodiment, the second conductive layer 303 may be disposed on the first coating layer 302 in the rigid portion 242. For example, the second conductive layer 303 may be disposed on an insulating portion 307 disposed on the first coating layer 302 and/or the second non-conductive layer 306 disposed on the insulating portion 307. For example, the insulating portion 307 may be a prepreg made of a reinforced fiber and a thermosetting resin, but is not limited thereto.

According to an embodiment, the second coating layer 304 may be disposed on the second conductive layer 303. The second coating layer 304 may be configured to cover a portion of the second conductive layer 303. For example, in the manufacturing process of the substrate 240, the second coating layer 304 may be disposed on the second conductive layer 303. An opening 304a may be formed in the second coating layer 304 to expose a portion of the second conductive layer 303. Through the opening 304a, a partial region of the second conductive layer 303 may be exposed to the outside of the substrate 240. The region of the second conductive layer 303 exposed through the opening 304a of the second coating layer 304 may be connected to another component. For example, the second conductive layer 303 may be connected to the connector connected to the first printed circuit board 251 and/or the second printed circuit board 252 through the opening 304a. However, the disclosure is not limited thereto.

According to an embodiment, a portion of the boundary of the first coating layer 302 may be aligned with the stepped portion 243. The first coating layer 302 may be exposed at the boundary between the rigid portion 242 and the flexible portion 241. The stepped portion 243 formed by a difference in the thickness between the rigid portion 242 and the flexible portion 241 may form a portion of the boundary of the rigid portion 242. At the boundary between the rigid portion 242 and the flexible portion 241, the stepped portion 243 may expose a portion of the rigid portion 242. For example, a portion of the boundary of the second coating layer 304 disposed in the rigid portion 242, a portion of the boundary of the second conductive layer 303, and a portion of the boundary of the first coating layer 302 may be exposed by the stepped portion 243. According to an embodiment, the portion of the boundary of the first coating layer 302 may be aligned with the stepped portion 243 and exposed.

According to an embodiment, the rigid portion 242 may include a first rigid portion 242a and a second rigid portion 242b. The first rigid portion 242a may be disposed closer to the first housing 210 among the first housing (e.g., the first housing 210 of FIG. 3A) and the second housing (e.g., the second housing 220 of FIG. 3A). The second rigid portion 242b may be disposed closer to the second housing 220 among the first housing 210 and the second housing 220. For example, the first rigid portion 242a may be connected to the connector (e.g., the first connector C1 of FIG. 3B) connected to the first printed circuit board 251, and the second rigid portion 242b may be connected to the connector (e.g., the second connector C2 of FIG. 3B) connected to the second printed circuit board 252. Referring to FIG. 3B, the hinge structure 260 may be disposed between the first housing 210 and the second housing 220. The first printed circuit board 251 may be disposed in the first housing 210. The second printed circuit board 252 may be disposed in the second housing 220. The substrate 240 may be connected to the first printed circuit board 251 and the second printed circuit board 252. According to an embodiment, the rigid portion 242 of the substrate 240 may be connected to the first printed circuit board 251 and/or the second printed circuit board 252 so that a portion connected to the first printed circuit board 251 and/or the second printed circuit board 252 may be stably fixed by being connected to the first printed circuit board 251 and/or the second printed circuit board 252.

According to an embodiment, the flexible portion 241 may be disposed between the first rigid portion 242a and the second rigid portion 242b. Among the substrate 240, since a shape of the substrate 240 between the first rigid portion 242a connected to the first printed circuit board 251 and the second rigid portion 242b connected to the second printed circuit board 252 is repeatedly deformed, the flexible portion 241 may be disposed between the first rigid portion 242a and the second rigid portion 242b. A shape of the flexible portion 241 may be repeatedly deformed based on an operation of the first housing 210 and the second housing 220. For example, when the first housing 210 and the second housing 220 operate, the position of the first rigid portion 242a may be changed according to movement of the first housing 210, and the position of the second rigid portion 242b may be changed according to movement of the second housing 220. As the positions of the first rigid portion 242a and the second rigid portion 242b are changed, the shape of the flexible portion 241 disposed between the first rigid portion 242a and the second rigid portion 242b may be at least partially deformed. At least a portion of the shape of the flexible portion 241 may be deformed based on a switch of the electronic device 101 from the unfolded state to the folded state or a switch of the electronic device 101 from the folded state to the unfolded state.

According to an embodiment, the first coating layer 302 may include a first portion 302a and a second portion 302b. The first portion 302a may be disposed, in the first conductive layer 301, on a first region 301a of the first conductive layer 301 corresponding to the first rigid portion 242a. The second portion 302b may be disposed, in the first conductive layer 301, on a second region 301b of the first conductive layer 301 corresponding to the second rigid portion 242b. The first portion 302a and the second portion 302b may be spaced apart from each other. In the manufacturing process of the substrate 240, a portion of the first coating layer 302 disposed on another portion of the first conductive layer 301 corresponding to the flexible portion 241 may be removed in the manufacturing process of the substrate 240. According to an embodiment, the first portion 302a on the first rigid portion 242a and the second portion 302b on the second rigid portion 242b of the first coating layer 302 may remain. The portion disposed on the flexible portion 241 of the first coating layer 302 may be removed in the manufacturing process of the substrate 240. By a removal process, the first portion 302a and the second portion 302b may be spaced apart from each other. The stepped portion 243 may be formed by the removal process.

According to an embodiment, a thickness of the first non-conductive layer 305 may be constant. Referring to FIG. 4B, a thickness of a portion of the first non-conductive layer 305 disposed in the flexible portion 241 may be substantially the same as a thickness of a portion of the first non-conductive layer 305 disposed in the rigid portion 242. For example, the portion of the first non-conductive layer 305 disposed within the rigid portion 242 may overlap other layers (e.g., the second conductive layer 303 and the second non-conductive layer 306) of the substrate 240. The portion of the first non-conductive layer 305 in the rigid portion 242 overlapped with other layers may be protected by other layers in the manufacturing process of the substrate 240. In the manufacturing process of the substrate 240, the portion of the first non-conductive layer 305 disposed in the flexible portion 241 may be protected by the first coating layer 302 before being removed. According to an embodiment, since the entire region of the first non-conductive layer 305 may be protected by the first coating layer 302 in the manufacturing process of the substrate 240, the thickness of the first non-conductive layer 305 may be maintained substantially uniform in the entire region. For example, the entire region of the first non-conductive layer 305 may be protected by the first coating layer 302 in the desmear process using chemicals. The first coating layer 302 may prevent and/or reduce a reaction between the first non-conductive layer 305 and the chemicals in the desmear process. According to an embodiment, when a portion of the first coating layer 302 disposed in the flexible portion 241 is removed, the first non-conductive layer 305 may be exposed to the outside of the substrate 240 in the flexible portion 241. The first non-conductive layer 305 may be disposed inside the substrate 240 in the rigid portion 242. The thickness of the portion of the first non-conductive layer 305 disposed in the flexible portion 241 and exposed to the outside may be substantially the same as the thickness of the portion of the first non-conductive layer 305 disposed in the rigid portion 242 and not exposed to the outside. For example, a thickness T1 of the first non-conductive layer 305 in the flexible portion 241 may be substantially the same as a thickness T2 of the first non-conductive layer 305 in the rigid portion 242. According to an embodiment, since the thickness of the first non-conductive layer 305 may be uniformly maintained in the manufacturing process of the substrate 240, durability and a life of the substrate 240 may be improved.

According to an embodiment, the rigid portion 242 may include a conductive via 310. The conductive via 310 may electrically connect the first conductive layer 301 and the second conductive layer 303. Referring to FIG. 4B, the substrate 240 may further include a third conductive layer 309 disposed between the second coating layer 304 and the second conductive layer 303, and connected to the conductive via 310. The third conductive layer 309 may be integrally formed with copper plating of a via hole (e.g., the via hole 320 of FIG. 7) penetrating the first conductive layer 301 and the second conductive layer 303. For example, between the second coating layer 304 and the second conductive layer 303, the third conductive layer 309 may be extended to an inner surface of the conductive via 310. The first conductive layer 301 and the second conductive layer 303 may be electrically connected through the third conductive layer 309. According to an embodiment, the conductive via 310 may be disposed in the rigid portion 242. For example, the conductive via 310 may include a first conductive via 310a disposed in the first rigid portion 242a and a second conductive via 310b disposed in the second rigid portion 242b. However, the disclosure is not limited thereto.

According to an embodiment, the second coating layer 304 may include the opening 304a exposing the third conductive layer 309. The substrate 240 may be electrically connected to the first printed circuit board 251 in the first housing 210 and the second printed circuit board 252 in the second housing 220 through the opening 304a. Referring to FIG. 4B, the second coating layer 304 may be disposed on the third conductive layer 309. The opening 304a of the second coating layer 304 may be formed through a process (e.g., etching) of removing a partial region of the second coating layer 304. A portion of the third conductive layer 309 may be exposed to the outside of the substrate 240 through the opening 304a. The third conductive layer 309 exposed through the opening 304a may be electrically connected to another component. For example, the portion of the third conductive layer 309 exposed through the opening 304a disposed in the first rigid portion 242a may be connected to the connector connected to the first printed circuit board 251. For example, the portion of the third conductive layer 309 exposed through the opening 304a disposed in the second rigid portion 242b may be connected to the connector connected to the second printed circuit board 252. However, the disclosure is not limited thereto.

According to an embodiment, the process for forming the opening 304a may be performed simultaneously with the process of removing a portion of the first coating layer 302 disposed in the flexible portion 241 of the first coating layer 302. According to an embodiment, the first coating layer 302 and the second coating layer 304 may include the same material. According to an embodiment, a material of the first coating layer 302 and a material of the second coating layer 304 may be a photo solder resist (PSR) ink. The PSR, as a permanent ink, may protect the conductive layer and reduce solder bridge between the conductive layers. A process of coating the PSR ink on the conductive layer (e.g., the third conductive layer 309), an exposure process, and a development process may be performed. When the material of the first coating layer 302 and the material of the second coating layer 304 are the same, the portion of the first coating layer 302 and the portion of the second coating layer 304 may be removed by a single process (e.g., etching).

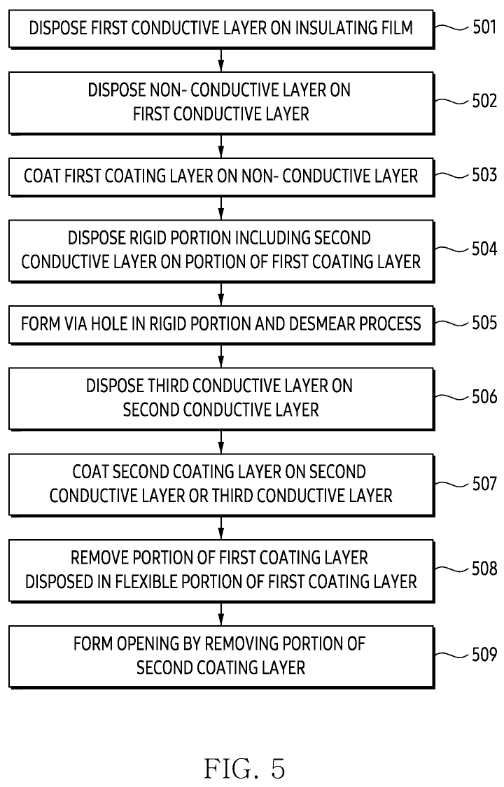

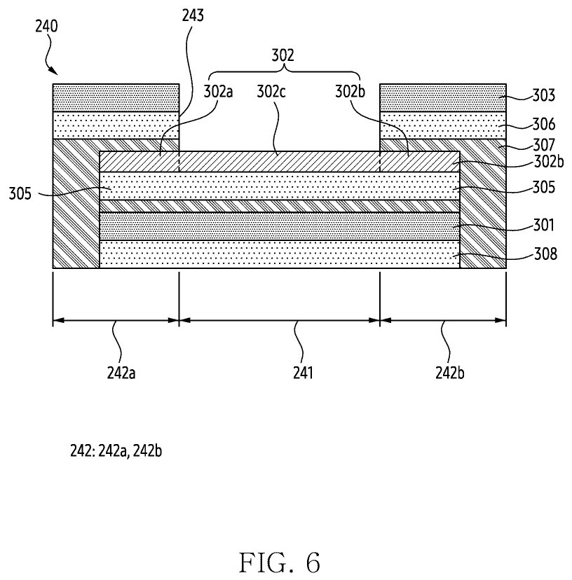

FIG. 5 is a flowchart illustrating an example method of manufacturing an example substrate 240 according to various embodiments. FIGS. 6, 7, 8, 9, and 10 are cross-sectional views illustrating example states of a substrate 240 during a manufacturing process according to various embodiments.

Referring to FIG. 5, in operation 501, a first conductive layer 301 may be disposed on an insulating film 308. The insulating film 308 may be a deformable film by having flexibility. The first conductive layer 301 may be stacked on the insulating film 308. For example, the operation 501 may be performed by attaching copper foil to the insulating film 308. For example, the operation 501 may be performed by sputtering a copper particle to the insulating film 308. However, the disclosure is not limited thereto.

In operation 502, a first non-conductive layer 305 may be disposed on the first conductive layer 301. For example, a polyimide coverlay film may be disposed on the first conductive layer 301. The first non-conductive layer 305 may be attached onto the first conductive layer 301 by an adhesive.

In operation 503, a first coating layer 302 may be coated on the first non-conductive layer 305. For example, the first coating layer 302 may be formed by applying a PSR ink on the first non-conductive layer 305. The first coating layer 302 may cover an entire region of the first non-conductive layer 305.

In operation 504, a rigid portion 242 including a second conductive layer 303 may be disposed on a portion of the first coating layer 302. Referring to FIG. 6, the rigid portion 242 may be disposed on the portion of the first coating layer 302. The rigid portion 242 may have relatively low flexibility. A portion where the rigid portion 242 is not disposed may be referred to as a flexible portion 241 having relatively high flexibility. For flexibility, a thickness of the flexible portion 241 may be thinner than a thickness of the rigid portion 242. Due to a difference between the thickness of the flexible portion 241 and the thickness of the rigid portion 242, a stepped portion 243 may be formed at a boundary between the flexible portion 241 and the rigid portion 242. A thickness of the stepped portion 243 may correspond to the difference between the thickness of the rigid portion 242 and the thickness of the flexible portion 241.

The flexible portion 241 may be different from the rigid portion 242. For example, the rigid portion 242 may include a second non-conductive layer 306 disposed on an insulating portion 307 (e.g., prepreg), and a second conductive layer 303 disposed on the second non-conductive layer 306. The flexible portion 241 may be referred to as a region where the rigid portion 242 is not disposed. The rigid portion 242 may include a first rigid portion 242a positioned on one side surface of the flexible portion 241 and a second rigid portion 242b positioned on another side surface of the flexible portion 241 opposite to the one side surface, but is not limited thereto. Since the rigid portion 242 is disposed on the portion of the first coating layer 302, another portion of the first coating layer 302 where the rigid portion 242 is not disposed may be referred to as a flexible portion.

Since the first coating layer 302 is coated on the first non-conductive layer 305 before the rigid portion 242 is disposed, the portion of the first coating layer 302 may at least partially overlap the rigid portion 242. According to an embodiment, the first coating layer 302 may include a first portion 302a, a second portion 302b, and a third portion 302c. The first portion 302a and the second portion 302b may be disposed on a portion of the first conductive layer 301 corresponding to the rigid portion 242. The first portion 302a and the second portion 302b may not be exposed to an outside of the substrate 240 by overlapping the rigid portion 242. The third portion 302c may be disposed on the remaining portion of the first conductive layer 301 corresponding to the flexible portion 241. The third portion 302c may be exposed to the outside of the substrate 240 by being spaced apart from the rigid portion 242.

In operation 505, a via hole 320 may be formed in the rigid portion 242, and a desmear process of removing a smear of the formed via hole 320 may be performed. Referring to FIG. 7, the via hole 320 may be disposed in the rigid portion 242. For example, the via hole 320 may penetrate the second conductive layer 303, the second non-conductive layer 306, and the insulating portion 307. According to an embodiment, the via hole 320 may include a first via hole 320a disposed in the first rigid portion 242a and a second via hole 320b disposed in the second rigid portion 242b. However, the disclosure is not limited thereto. The via hole 320 may be formed through a mechanical drill and/or a laser drill. To remove a burr, a chip, and/or a resin residue generated in a drilling process of the via hole 320, and to clean a surface of the substrate 240, the desmear process may be performed. For example, the desmear process may be performed by the chemicals including permanganate (e.g., sodium permanganate and gallium permanganate) and caustic substances to remove the resin residue generated by heat and pressure from the drill in the drilling process. Through the desmear process, the smear of the via hole 320 may be removed and the surface of the substrate 240 may be cleaned.

According to an embodiment, in the desmear process, the first non-conductive layer 305 may be protected by the first coating layer 302. The first non-conductive layer 305 may be damaged by the chemicals used in the desmear process. As the desmear process is repeated, durability of the first non-conductive layer 305 protecting the first conductive layer 301 may be reduced. The first conductive layer 301 and the first non-conductive layer 305 may receive force by an operation in which the flexible portion 241 is curved or unfolded. In case that the durability of the first non-conductive layer 305 is reduced, as a folding operation or an unfolding of an electronic device (e.g., the electronic device 101 of FIG. 3A) is repeated, it may be easily damaged. According to an embodiment, in the desmear process, since the first coating layer 302 protects the first non-conductive layer 305, damage to the first non-conductive layer 305 may be reduced.

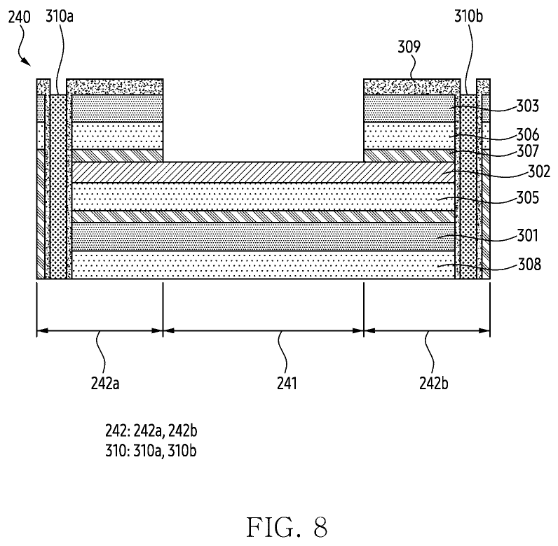

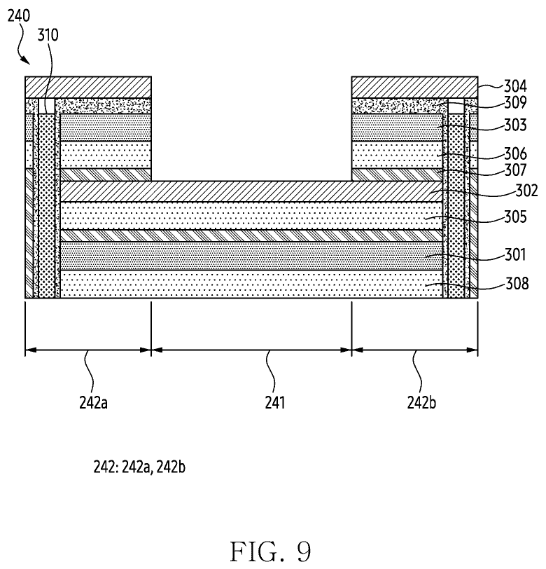

In operation 506, a third conductive layer 309 may be disposed on the second conductive layer 303. Referring to FIG. 8, the third conductive layer 309 may integrally form the via hole 320 penetrating the first conductive layer 301 and the second conductive layer 303 with a copper plating. For example, the third conductive layer 309 may extend to an inner peripheral surface of a conductive via 310 between a second coating layer 304 (e.g., a second coating layer 304 of FIG. 9) and the second conductive layer 303. The first conductive layer 301 and the second conductive layer 303 may be electrically connected through the third conductive layer 309. According to an embodiment, the conductive via 310 may be disposed in the rigid portion 242. For example, the conductive via 310 may include a first conductive via 310a disposed in the first rigid portion 242a and a second conductive via 310b disposed in the second rigid portion 242b. However, the disclosure is not limited thereto.

In operation 507, the second coating layer 304 may be coated on the second conductive layer 303 or the third conductive layer 309. Referring to FIG. 9, the second coating layer 304 may be configured to cover a portion of the second conductive layer 303 or the third conductive layer 309. Since the second conductive layer 303 and/or the third conductive layer 309 of the rigid portion 242 forms an outermost layer of the substrate 240, the second coating layer 304 may be coated to protect the second conductive layer 303 and/or the third conductive layer 309. According to an embodiment, the first coating layer 302 and the second coating layer 304 may include the same material. According to an embodiment, a material of the first coating layer 302 and a material of the second coating layer 304 may be the photo solder resist (PSR) ink. However, the disclosure is not limited thereto. The second coating layer 304 may be selectively photocured through an exposure process.

In operation 508, a portion of the first coating layer 302 disposed in the flexible portion 241 of the first coating layer 302 may be removed. According to an embodiment, the portion of the first coating layer 302 disposed on the flexible portion 241 of the first coating layer 302 may be removed. The first portion 302a and the second portion 302b of the first coating layer 302 may overlap the rigid portion 242. The third portion 302c of the first coating layer 302 disposed in the flexible portion 241 may be removed through a removal process. Since the first coating layer 302 coated to protect the first non-conductive layer 305 in the desmear process is unnecessary after the desmear process is completed, it may be removed through an etching process. The third portion 302c may be removed by a physical method distinguished from a chemical method. For example, the first coating layer 302 may include a tear portion formed along a boundary of the third portion 302c. The tear portion may be a pre-scored portion. The tear portion may be easily torn off by an external force.

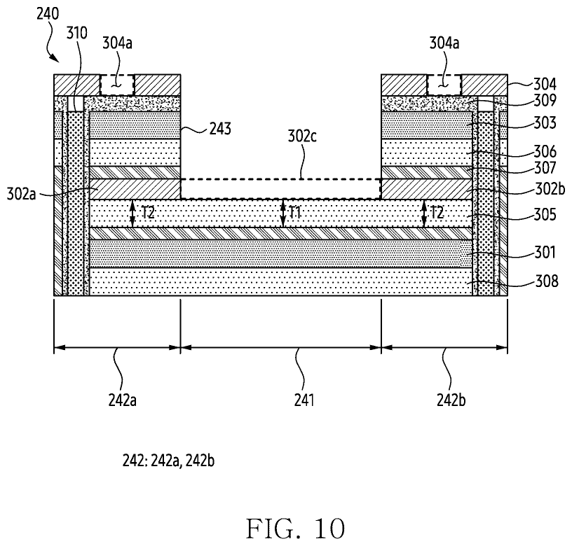

Referring to FIG. 10, a portion of the boundary of the first coating layer 302 may be aligned with the stepped portion 243. Since the third portion 302c is removed, a portion of the first non-conductive layer 305 disposed in the flexible portion 241 may be exposed. Since the first portion 302a and the second portion 302b overlap the rigid portion 242, they may be maintained in the removal process. Since the first portion 302a and the second portion 302b are maintained, a portion of the boundary of the first portion 302a and a portion of the boundary of the second portion 302b may be aligned with the stepped portion 243 formed at the boundary between the rigid portion 242 and the flexible portion 241.

According to an embodiment, a thickness of the first non-conductive layer 305 may be maintained substantially constantly over the entire region. Since the first non-conductive layer 305 may be protected by the first coating layer 302 during the desmear process, damage to the first non-conductive layer 305 may be reduced. According to an embodiment, a thickness T1 of the first non-conductive layer 305 disposed in the flexible portion 241 may be substantially the same as a thickness T2 of the first non-conductive layer 305 disposed in the rigid portion 242.

In operation 509, an opening 304a may be formed in the second coating layer 304 to expose a portion of the second conductive layer 303 or the third conductive layer 309. Through the opening 304a, a partial region of the portion of the second conductive layer 303 or the third conductive layer 309 may be exposed to the outside of the substrate 240. The region of the second conductive layer 303 or the third conductive layer 309 exposed through the opening 304a of the second coating layer 304 may be connected to another component. For example, the second conductive layer 303 or the third conductive layer 309 may be connected to a connector connected to the first printed circuit board 251 and/or the second printed circuit board 252 through the opening 304a. However, the disclosure is not limited thereto.

According to an embodiment, since the material of the first coating layer 302 and the material of the second coating layer 304 may be the same, a portion of the first coating layer 302 and a portion of the second coating layer 304 may be removed by a single process. The operations 508 and 509 may be performed simultaneously. Using the chemicals for etching the PSR ink, the removal of the third portion 302c and formation of the opening 304a may be performed through the single process. For example, in case that masking is disposed in the remaining portion of the second coating layer 304 except for the portion where the opening 304a is formed, and the etching process is performed, the removal of the third portion 302c and the formation of the opening 304a may be performed simultaneously. According to an embodiment, the manufacturing process of the substrate 240 may be simplified.

Embodiments of the disclosure improve the durability and a life of the substrate by protecting the non-conductive layer in the manufacturing process of the substrate. However, the present disclosure is not limited to the above-described contents.

An electronic device (e.g., the electronic device 101 of FIG. 3A) according to an example embodiment may include: a first housing (e.g., the first housing 210 of FIG. 3A), a second housing (e.g., the second housing 220 of FIG. 3A), a hinge structure comprising a hinge (e.g., the hinge structure 260 of FIG. 3A), and a substrate (e.g., the substrate 240 of FIG. 3A). The hinge structure may rotatably connect the first housing and the second housing. The substrate may extend from an inside of the first housing across the hinge structure to an inside of the second housing. The substrate may include a flexible portion (e.g., the flexible portion 241 of FIG. 4B), a rigid portion (e.g., the rigid portion 242 of FIG. 4B), and a stepped portion (e.g., the stepped portion 243 of FIG. 4B). The stepped portion may be disposed at a boundary between the flexible portion and the rigid portion. The substrate may include a first conductive layer (e.g., the first conductive layer 301 of FIG. 4B), a first coating layer (e.g., the first coating layer 302 of FIG. 4B), a second conductive layer (e.g., the second conductive layer 303 of FIG. 4B), and a second coating layer (e.g., the second coating layer 304 of FIG. 4B). The first conductive layer may be disposed in the flexible portion and the rigid portion. The first coating layer may be disposed on a portion of the first conductive layer corresponding to the rigid portion. The second conductive layer may be disposed on the first coating layer in the rigid portion. The second coating layer may be disposed on the second conductive layer. A portion of a boundary of the first coating layer may be aligned with the stepped portion. According to various embodiments, the first coating layer may protect layers in the flexible portion. For example, in a desmear process during a manufacturing process, the first coating layer may protect the flexible portion from chemicals used in the desmear process. According to various embodiments, damage to the flexible portion may be reduced. According to various embodiments, a shape of the flexible portion may be deformed according to an operation of the first housing and the second housing. Since the damage in the flexible portion is reduced, durability and a life of the flexible portion may be improved.

According to an example embodiment, the rigid portion may include a first rigid portion (e.g., the first rigid portion 242a of FIG. 4B), and a second rigid portion (e.g., the second rigid portion 242b of FIG. 4B). The first rigid portion may be disposed closer to the first housing of the first housing and the second housing. The second rigid portion may be disposed closer to the second housing of the first housing and the second housing.

According to an example embodiment, the flexible portion may be disposed between the first rigid portion and the second rigid portion.

According to an example embodiment, the first coating layer may include a first portion (e.g., the first portion 302a of FIG. 4B), and a second portion (e.g., the second portion 302b of FIG. 4B). The first portion may be disposed on a first region (e.g., the first region 301a of FIG. 4B) of the first conductive layer corresponding to the first rigid portion in the first conductive layer. The second portion may be disposed on a second region (e.g., the second region 301b of FIG. 4B) of the first conductive layer corresponding to the second rigid portion in the first conductive layer. The first portion and the second portion may be spaced apart each other. According to an example embodiment, the substrate may include the first rigid portion connected to an inside of the first housing and the second rigid portion connected to an inside of the second housing. A flexible portion may be disposed between the first rigid portion and the second rigid portion. The first rigid portion may be configured to move according to a movement of the first housing, and the second rigid portion may be configured to move according to a movement of the second housing. Based on the first housing and the second housing moving, a shape of the flexible portion between the first rigid portion and the second rigid portion may be deformed.

According to an example embodiment, the substrate may include a non-conductive layer (e.g., the first non-conductive layer 305 of FIG. 4B). The non-conductive layer may be disposed between the first coating layer and the first conductive layer. A thickness (e.g., the thickness T1 of FIG. 4B) of the non-conductive layer disposed in the flexible portion may be the same as a thickness (e.g., the thickness T2 of FIG. 4B) of the non-conductive layer disposed in the rigid portion. According to an example embodiment, the non-conductive layer may be protected by the first coating layer in a manufacturing process. By protecting the non-conductive layer, the thickness of the non-conductive layer may be maintained substantially constantly over an entire region. Since the non-conductive layer may be protected, damage to the flexible portion may be reduced. According to various embodiments, durability and a life of the flexible portion may be improved.

According to an example embodiment, the non-conductive layer may be exposed to an outside of the substrate in the flexible portion. The non-conductive layer may be disposed in an inside of the substrate in the rigid portion. According to an example embodiment, the non-conductive layer may include a portion disposed inside the substrate by overlapping the rigid portion and a portion disposed outside the substrate by being disposed in the flexible portion. Since the non-conductive layer is protected by a first coating layer, a constant thickness may be maintained regardless of whether the non-conductive layer is disposed inside or outside the substrate.

According to an example embodiment, the rigid portion may include a conducive via (e.g., the conductive via 310 of FIG. 4B). The conducive via may electrically connect the first conductive layer and the second conductive layer. The substrate may include a third conductive layer (e.g., the third conductive layer 309 of FIG. 4B). The third conductive layer may be disposed between the second coating layer and the second conductive layer. The third conductive layer may be connected to the conductive via.

According to an example embodiment, the second coating layer may include an opening (e.g., the opening 304a of FIG. 4B) exposing the third conductive layer. According to an example embodiment, the third conductive layer may be connected to another component through the opening. For example, a connector of a first printed circuit board or a connector of a second printed circuit board may be connected to the third conductive layer through the opening. The opening may be formed by removing a portion of the second protective layer.

According to an example embodiment, the substrate may be connected to a first printed circuit board in the first housing and a second printed circuit board in the second housing, through the opening.

According to an example embodiment, a material of the first coating layer may be the same as a material of the second coating layer.

According to an example embodiment, a material of the first coating layer and a material of the second coating layer may include a photo solder resist (PSR) ink. According to an example embodiment, since the first coating layer and the second coating layer have the same material, a portion of the first coating layer and a portion of the second coating layer may be removed through a single process. For example, the process of removing the portion disposed in a flexible portion of the first coating layer and the process of forming an opening of the second coating layer may be performed simultaneously.

The electronic device according to an example embodiment may further include: a first printed circuit board (e.g., the first printed circuit board 251 of FIG. 3B) and a second printed circuit board (e.g., the second printed circuit board 252 of FIG. 3B). The first printed circuit board may be disposed in the first housing. The second printed circuit board may be disposed in the second housing. The substrate may be connected to the first printed circuit board and the second printed circuit board. According to an example embodiment, the first printed circuit board and the second printed circuit board may be connected to each other through the substrate.

At least a portion of the substrate may be disposed in the hinge structure. In order to be connected to the first printed circuit board and the second printed circuit board, the substrate may be disposed in the hinge structure. A flexible portion of the substrate may be curved or unfolded according to an operation of the hinge structure. Since a shape of the substrate may be deformed, the substrate may connect the first printed circuit board and the second printed circuit board in the hinge structure.

According to an example embodiment, the electronic device may include a display (e.g., the display 230 of FIG. 2A). The first housing may include a first surface (e.g., the first surface 211 of FIG. 3B) and a second surface (e.g., the second surface 212 of FIG. 3B). The first surface may face the display. The second surface may be opposite to the first surface. The second housing may include a third surface (e.g., the third surface 221 of FIG. 3B) and a fourth surface (e.g., the fourth surface 222 of FIG. 3B). The third surface may face the display. The fourth surface may be opposite to the third surface. The hinge structure may be configured to provide an unfolded state in which a direction of the first surface corresponds to a direction of the third surface, or a folded state in which the first surface faces the third surface, by rotatably connecting the first housing and the second housing. The hinge structure may be configured to provide an intermediate state between the unfolded state and the folded state.

According to an example embodiment, a shape of at least a portion of the flexible portion may be deformed based on the electronic device switching from the unfolded state to the folded state or the electronic device switching from the folded state to the unfolded state. According to an example embodiment, a substrate may include a plurality of flexible portions. The flexible portion disposed in the hinge structure may be curved or unfolded based on a state of the electronic device changing. The flexible portion may have flexibility. Since a shape of the flexible portion may be deformed according to the state change of the electronic device, the substrate may stably connect a first printed circuit board and a second printed circuit board.

According to an example embodiment, a method of manufacturing of a substrate may include: disposing a first conductive layer on a dielectric film, disposing a non-conductive layer on the first conductive layer, coating a first coating layer on the non-conductive layer, disposing a rigid portion including a second conductive layer on a portion of the first coating layer, forming a via hole in the rigid portion and removing a smear of the formed via hole, coating a second coating layer on the second conductive layer, and removing the first coating layer disposed in a flexible portion of the first coating layer. According to an example embodiment, the first coating layer may protect layers in the flexible portion. In a desmear process, the first coating layer may protect the flexible portion from chemicals used in the desmear process. Since the first coating layer is removed after the desmear process is completed, damage to the non-conductive layer during the desmear process may be reduced. According to an embodiment, a shape of the flexible portion may be deformed according to an operation of a first housing and a second housing. Since damage in the flexible portion is reduced, durability and a life of the flexible portion may be improved.

According to an example embodiment, forming an opening by removing a portion of the second coating layer may be further included.

According to an example embodiment, disposing a third conductive layer, between the second coating layer and the second conductive layer, extending to the via hole may be further included. According to an example embodiment, the third conductive layer may be connected to another component through an opening. For example, a connector of a first printed circuit board or a connector of a second printed circuit board may be connected to the third conductive layer through the opening. The opening may be formed by removing a portion of a second protective layer.

According to an example embodiment, a material of the first coating layer may be the same as a material of the second coating layer.

According to an example embodiment, a material of the first coating layer and a material of the second coating layer may include a photo solder resist (PSR) ink. According to an example embodiment, since the first coating layer and the second coating layer have the same material, a portion of the first coating layer and a portion of the second coating layer may be removed through a single process. For example, since a process of removing the portion disposed in the flexible portion of the first coating layer and a process of forming an opening of the second coating layer may be performed simultaneously, a manufacturing process may be simplified.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
a first housing;
a second housing;
a hinge structure comprising a hinge rotatably connecting the first housing and the second housing; and
a substrate, extending from an inside of the first housing across the hinge structure to an inside of the second housing, the substrate including:
a flexible portion,
a rigid portion, and
a stepped portion disposed at a boundary between the flexible portion and the rigid portion,
wherein the substrate includes:
a first conductive layer disposed in the flexible portion and the rigid portion,
a first coating layer disposed on a portion of the first conductive layer corresponding to the rigid portion,
a second conductive layer disposed on the first coating layer in the rigid portion, and
a second coating layer disposed on the second conductive layer, and
wherein a portion of a boundary of the first coating layer is aligned with the stepped portion.

2. The electronic device of claim 1,
wherein the rigid portion includes:
a first rigid portion disposed closer to the first housing of the first housing and the second housing, and
a second rigid portion disposed closer to the second housing of the first housing and the second housing.

3. The electronic device of claim 2,
wherein the flexible portion is disposed between the first rigid portion and the second rigid portion.

4. The electronic device of claim 2,
wherein the first coating layer includes:
a first portion disposed on a first region of the first conductive layer corresponding to the first rigid portion in the first conductive layer, and
a second portion disposed on a second region of the first conductive layer corresponding to the second rigid portion in the first conductive layer, and
wherein the first portion of the first coating layer and the second portion of the first coating layer are spaced apart each other.

5. The electronic device of claim 1,
wherein the substrate includes a non-conductive layer disposed between the first coating layer and the first conductive layer, and
wherein a thickness of the non-conductive layer disposed in the flexible portion corresponds to a thickness of the non-conductive layer disposed in the rigid portion.

6. The electronic device of claim 5,
wherein the non-conductive layer is exposed to an outside of the substrate in the flexible portion of the substrate, and is disposed in an inside of the substrate in the rigid portion of the substrate.

7. The electronic device of claim 1,
wherein the rigid portion of the substrate includes a conducive via electrically connecting the first conductive layer and the second conductive layer, and
wherein the substrate includes a third conductive layer, disposed between the second coating layer and the second conductive layer, connected to the conductive via.

8. The electronic device of claim 7,
wherein the second coating layer includes an opening exposing the third conductive layer.

9. The electronic device of claim 8,
wherein the substrate is connected to a first printed circuit board (PCB) in the first housing and a second PCB in the second housing, through the opening.

10. The electronic device of claim 1,
wherein a material of the first coating layer is the same material as a material of the second coating layer.

11. The electronic device of claim 1,
wherein a material of the first coating layer and a material of the second coating layer comprise a photo solder resist (PSR) ink.

12. The electronic device of claim 11, further comprising:
a first PCB disposed in the first housing; and
a second PCB disposed in the second housing,
wherein the substrate is connected to the first PCB and the second PCB.

13. The electronic device of claim 12,
wherein at least a portion of the substrate is disposed in the hinge structure.

14. The electronic device of claim 1, further comprising a display,
wherein the first housing includes:
a first surface facing the display, and
a second surface opposite to the first surface,
wherein the second housing includes:
a third surface facing the display, and
a fourth surface opposite to the third surface, and
wherein the hinge structure is configured to provide an unfolded state of the electronic device in which a direction of the first surface of the first housing corresponds to a direction of the third surface of the second housing, or a folded state of the electronic device in which the first surface of the first housing faces the third surface of the second housing, by rotatably connecting the first housing and the second housing.

15. The electronic device of claim 14,
wherein a shape of at least a portion of the flexible portion of the substrate is configured to be deformed based on a state change of the electronic device.

16. A method of manufacturing of a substrate including:
disposing a first conductive layer on a dielectric film;
disposing a non-conductive layer on the first conductive layer;
coating a first coating layer on the non-conductive layer;
disposing a rigid portion including a second conductive layer on a portion of the first coating layer;
forming a via hole in the rigid portion and removing a smear of the via hole;
coating a second coating layer on the second conductive layer; and
removing a portion of the first coating layer disposed in a flexible portion different from the rigid portion, in the first coating layer.

17. The method of claim 16, further comprising forming an opening by removing a portion of the second coating layer.

18. The method of claim 16, further comprising disposing a third conductive layer, between the second coating layer and the second conductive layer, and extending to the via hole.

19. The method of claim 16,
wherein a material of the first coating layer is the same material as a material of the second coating layer.

20. The method of claim 16,
wherein a material of the first coating layer and a material of the second coating layer comprise a photo solder resist (PSR) ink.
